(19) United States
(12) Patent Application Publication
(10) Pub. No.: US 2026/0072108 A1
(43) Pub. Date: Mar. 12, 2026

(54) METHOD AND APPARATUS FOR REDUCING THE NOISE TEMPERATURE OF SYSTEMS COMPRISING SAMPLES WHICH INTERACT WITH OSCILLATING ELECTROMAGNETIC FIELDS SUPPORTED BY ELECTROMAGNETIC RESONATORS

(71) Applicant: IMPERIAL COLLEGE INNOVATIONS LIMITED, LONDON (GB)

(72) Inventors: CHEN KUAN-CHENG, LONDON (GB); MARK OXBORROW, LONDON (GB)

(73) Assignee: IMPERIAL COLLEGE INNOVATIONS LIMITED, LONDON, EN (GB)

(21) Appl. No.: 19/106,247

(22) PCT Filed: Aug. 25, 2023
(86) PCT No.: PCT/GB2023/052214

§ 371 Date: Feb. 25, 2025

(30) Foreign Application Priority Data
Aug. 26, 2022 (GB) 2212465.5

(51) Int. Cl. G01R 33/385; G01R 33/60

(52) U.S. Cl. CPC G01R 33/385; G01R 33/60

(57) ABSTRACT

An aspect of the disclosure provides an apparatus comprising: an electromagnetic resonator configured to support an oscillating electromagnetic field in a sample; a cold load having a noise temperature lower than the noise temperature of the electromagnetic resonator; a coupler controllable to provide: a first coupling between the electromagnetic resonator and the cold load to reduce the noise temperature of the electromagnetic resonator; a second coupling, different from the first coupling, to the electromagnetic resonator for sensing an electromagnetic field associated with the sample.

### FIELD OF INVENTION

The present invention relates to methods and apparatus, and more particularly to methods and apparatus for reducing the noise temperature of systems comprising samples which interact with oscillating electromagnetic fields supported by electromagnetic resonators.

### BACKGROUND

Electromagnetic resonators include systems such as microwave cavities, for use in electron paramagnetic resonance systems, and RF resonators for use in nuclear magnetic resonance systems. Electromagnetic resonators may also be used for interaction with qubits in quantum computing systems such as flux qubits and charge qubits. Qubits may comprise a single spin-like system located in microwave resonator or “cavity”.

To improve sensing it is often desired to reduce the thermal noise present in a system. The term “noise temperature” is often used to quantify how much thermal noise is present in a system.

Electromagnetic resonators exhibit certain resonance modes at particular frequencies. According to the rules of cavity quantum electrodynamics (CQED), each such mode can be “second-quantized”, where its quantum state is characterized by the number of photons that the mode contains as well as by its coherence properties. To perform useful quantum operations, the incoherent thermal photons that occupy the mode, which are responsible for undesired measurement noise, need to be removed. One way to reduce thermal noise is by cooling.

Cooling an electromagnetic resonator can be done in a dilution refrigerator, which may achieve temperatures of a few tens of millikelvin. Though unable to achieve such low temperatures, recent studies have demonstrated the removal of thermal photons from particular microwave modes inside room-temperature cavities through stimulated absorption by a spin-cold (and thus highly spin-polarized) medium within the cavity. Examples of such approaches are described by H. Wu, S. Mirkhanov, W. Ng, and M. Oxborrow, Bench top cooling of a microwave mode using an optically pumped spin refrigerator, Physical Review Letters 127, 053604 (2021). and W. Ng, H.Wu, and M. Oxborrow, Quasi-continuous cooling of a microwave mode on a benchtop using hyperpolarized nv-diamond, Applied Physics Letters 119, 234001 (2021).

Wu et al. demonstrated cooling by means of a polarized spin bath of pentacene crystal to remove thermal energy from a microwave cavity. Ng et al. demonstrated a quasi-continuous cooling by using photoexcited negatively charged nitrogen vacancies (NV−) in diamonds as the cryo-spin-polarized absorber. These demonstrations reveal a selective cooling of an EM mode, thus a “spin refrigerator”.

These approaches require powerful optical pumping sources, generally lasers, to achieve the required spin polarization which makes the whole set-up still rather bulky and energy-consuming.

Furthermore, such a spin refrigerator can only cool over the narrow band of frequencies that lie, in frequency, under the spin-polarized transition being exploited. The linewidth of such a transition, whose absolutely frequency typically lies in the GHz range, rarely exceed a few MHz. The fractional bandwidth of such a spin refrigerator is thus, at best, a few percent.

Several decades ago, in radiometry, it was demonstrated that a coaxial termination immersed in liquid helium and connected through low-loss waveguide is capable of absorbing thermal photons. The mode cooling achievable by such a cryogenic load is far broader band and enables useful applications, such as improving the SNR of quantum sensing.

### SUMMARY

Aspects and examples of the present invention are set out in the claims and aim to address the above-described technical problem and other problems.

An aspect provides an apparatus comprising:
an electromagnetic resonator configured to support an oscillating electromagnetic field in a sample;
a cold load having a noise temperature lower than the noise temperature of the electromagnetic resonator;
a coupler controllable to provide:
   a first coupling between the electromagnetic resonator and the cold load to reduce the noise temperature of the electromagnetic resonator;
   a second coupling, different from the first coupling, to the electromagnetic resonator for sensing an electromagnetic field associated with the sample.

Embodiments of the disclosure may address the technical problem of how to reduce the noise temperature of the electromagnetic resonator and the sample prior to interrogation of such a sample by means of electromagnetic fields. The modes of the resonator and the electromagnetic fields associated with the sample may correspond to resonant frequencies of the sample, such as the Larmor frequency of the sample.

The sample may comprise a spin or spin-like system which interacts with the oscillating electromagnetic field supported by the resonator. The apparatus may be provided in a magnetic field, B₀, which provides for such resonant behaviour of the sample. The electromagnetic field associated with the sample may result from the relaxation of the sample from an excited state caused by the application of electromagnetic energy, which may be applied using the second coupling.

The return, or relaxation, of the spins back to their pre-excited state releases electromagnetic energy e.g., in the form of a free induction decay, FID, or in the form of a spin, which can be sensed by the second coupling to provide information about the characteristics of the spin system.

The problems addressed by this and other embodiments of the claims may be particularly significant in known systems in which the sample comprises spins (such as nuclear spins and electrons) which are excited by the application of electromagnetic energy.

For example the sample may comprise polarised electron spins, the resonator may be a microwave resonant cavity, and the second coupling may be provided by an inductive coupling, such as is associated with a coil tuned to interact with the electron spins. As another example, the sample may comprise polarised nuclear spins and the resonator may be provided by an LCR circuit tuned to interact with the nuclear spins, such as a transmit/receive coil of an NMR system. In such systems the coupling may be provided electrically, e.g. via a matching network.

It can thus be seen that examples of samples which can be interrogated in this way include samples of nuclear spins, which can be interrogated by way of nuclear magnetic resonance and samples comprising electron spin systems, which can be interrogated by way of electron paramagnetic resonance.

Other examples of samples to which this and other embodiments of the claims can be applied comprise qubits and quantum information processors, such as transmons, and quantum spin memory, where the qubit is interrogated its with the via interaction electromagnetic resonator. Most transmons to date have used resonant lengths (equal to either a quarter or half a wavelength) of serpentine co-planar waveguide, where this waveguide is made from lithographically printed/etched titanium metal on a sapphire substrate

In these examples the electromagnetic resonator would be provided by either a 3D cavity, or a dielectric resonator, or a resonant length of waveguide (e.g. coplanar). In such systems, the coupler may be provided by either a varactor, in the case of an adjustable capacitive coupling, or a microwave switch based on FETs or PIN diodes for connecting and disconnecting inductive loops. This can enable the coupler to switch between overcoupled and critically coupled states.

Some types of qubit, known as “flux q-bits” can interact magnetically (e.g. via magnetic field) with the electromagnetic resonator. Other types of qubit, known as “charge q-bits” may interact electrically (e.g. via electric field of resonator) with the electromagnetic resonator.

Some embodiments of the present disclosure relate to methods and apparatus for overcoming the thermal-noise limit of microwave measurements at room temperature by pre-cooling with a low-noise amplifier. Such methods and apparatus may have particular application to time-resolved Electron Paramagnetic Resonance, EPR and to other types of systems including electromagnetic resonators.

The present disclosure aims to provide cooling of electromagnetic resonators across a broad band of frequencies using compact and inexpensive equipment. An embodiment may comprise using a an HEMT-based low noise amplifier (LNA) to serve as a cold load.

These and other types of cold load may be over-coupled to a resonator such as a microwave cavity of an EPR spectrometer.

Such embodiments may provide reduction of the noise temperature of a microwave mode of a microwave cavity of an EPR spectrometer, for example to 65 K, while the physical temperature of the cold load may be at a substantially higher temperature (e.g. room temperature). This may directly improve the signal-to-noise ratio of the transient EPR spectrometer in a room-temperature environment.

Simulations based on the present pre-cooling technique, applied to a microwave cavity, show the capability of cooling the microwave mode's temperature to a few K (corresponding to tens of microwave photons) for a long duration (second-timescale). This cavity-pre-cooling scheme may provide a broadband and extremely convenient platform-free of optical pumping, cryogenics, vacuum system and strong magnets. Also, this technique can be used as a primary or secondary cooling system for achieving a higher SNR for quantum sensing and quantum information processing, such as EPR or NMR.

In an aspect there is provided an apparatus comprising:
an electromagnetic resonator configured to support an oscillating electromagnetic field in a sample;
a cold load having a noise temperature lower than the noise temperature of the electromagnetic resonator;
a coupler controllable to provide:
   a first coupling between the electromagnetic resonator and the cold load to reduce the noise temperature of the electromagnetic resonator;
   a second coupling, different from the first coupling, to the electromagnetic resonator for sensing an electromagnetic field associated with the sample.

The coupler may be configured to disable the first coupling prior to the sensing. The first coupling and the second coupling may comprise inductive couplings, such as may be provided via the H-between inductive elements, or may be provided by filed electrical coupling, for example mediated by the electric field for example conductively and/or capacitively.

The coupler is arranged so that a coupling factor of the first coupling is greater than a coupling factor of the second coupling, for example the first coupling may be overcoupled and/or the second coupling may be critically coupled.

The cold load may be provided by an input of a low noise amplifier.

The apparatus may comprise a switching element between the coupler and the cold load. The switching element may be operable to disable the first coupling, for example by disconnecting it from the cold load to provide an open circuit termination.

The switching element may have a sufficiently low insertion loss that the noise temperature at its connection to the coupler is substantially equal to the noise temperature of the cold load.

The switching element may comprise a switchable conduction channel and provides sufficiently high isolation of the switchable conduction channel that the noise temperature at its connection to the coupler element is substantially equal to the noise temperature of the cold load.

The coupler may comprise:
an auxiliary coupler connectable to the cold load wherein the auxiliary coupler provides the first coupling,
a sensing coupler for connection to a receiver for performing the sensing, wherein the sensing coupler provides the second coupling; and
wherein the coupling factor of the auxiliary coupler to the electromagnetic resonator is greater than the coupling factor of the sensing coupler to the electromagnetic resonator.

The switching element may switchably connect the cold load to the auxiliary coupler.

The cold load may be provided by an active cold load such as an input of a low noise amplifier, for example the LNA of the front end of a receiver for performing the sensing. The input of the receiver may be switchably connected to the sensing coupler.

The switching element may be switchable from (a) a cooling mode in which it connects both the auxiliary coupler and sensing coupler to the low noise amplifier input of a receiver; to (b) a sensing mode in which it connects only the sensing coupler to a low noise amplifier input of the receiver.

The switching element may be provided by a microwave switch.

The switching element may have a switching time, t_{switch}, which is small compared with a thermalisation time of the electromagnetic resonator, for example wherein

$${t}_{switch} ≪ \frac{{Q}_{0}}{2 π f}$$

### Where:

Q₀ is the Q-factor of the electromagnetic resonator and
f is the resonant frequency of the electromagnetic resonator.

The switching time may be less than 20% of the thermalisation time, for example 10% or less.

The second coupling may be critically coupled, for example substantially critically coupled.

Embodiments provide an electron paramagnetic resonance, EPR, system comprising the apparatus described and/or claimed herein wherein the electromagnetic resonator is provided by a resonant cavity disposed in a magnetic field, B₀, the cavity configured so that the sample can be disposed in the cavity and the sensing comprises an EPR measurement of the sample. The magnetic field, B₀ may be time varying.

Embodiments provide a nuclear magnetic resonance, NMR, system comprising the apparatus described and/or claimed herein, wherein the electromagnetic resonator is provided by a transmit/receive coil of the NMR system disposed in a magnetic field, B₀, and the sensing comprises an NMR measurement of the sample.

The cold load may comprise at least one of: a cryogenic load, and an active cold noise source such as an input of a low noise termination or a low noise amplifier (LNA).

An aspect also provides a method of reducing the noise temperature of an electromagnetic resonator configured to support an oscillating magnetic field in a sample, the method comprising: providing a first coupling between the electromagnetic resonator and a cold load having a noise temperature lower than a noise temperature of the electromagnetic resonator; and, when the noise temperature of the electromagnetic resonator has been reduced, providing a second coupling to the electromagnetic resonator for sensing an electromagnetic field associated with the sample, the first coupling being different from the second coupling.

The method may comprise disabling the first coupling prior to performing the sensing.

Providing the second coupling may comprise disconnecting the cold load from a coupler arranged for coupling with the electromagnetic fields associated with the sample, wherein the sensing is performed after the disconnecting.

The disconnecting may be performed quickly, for example in a switching time, t_{switch}, which is small compared with a thermalisation time of the electromagnetic resonator, for example wherein

$${t}_{switch} ≪ \frac{{Q}_{0}}{2 π f}$$

### Where:

Q₀ is the Q-factor of the electromagnetic resonator and
f is the resonant frequency of the electromagnetic resonator.

A coupling factor of the first coupling may be greater than a coupling factor of the second coupling, for example the first coupling may be overcoupled and/or the second coupling may be critically coupled, for example substantially critically coupled.

The cold load may be provided by any passive or active cold load such as an input of a low noise amplifier.

An aspect provides a method of preparing an electron paramagnetic resonance, EPR, apparatus for performing an EPR measurement of a sample in a resonant cavity of the apparatus, the method comprising performing any method described or claimed herein to reduce the noise temperature of the cavity.

An aspect provides a method of preparing a nuclear magnetic resonance, NMR, apparatus for performing an NMR measurement of a sample in a transmit/receive coil of the NMR system, the method comprising performing any method described or claimed herein to reduce the noise temperature of the transmit/receive coil.

An aspect provides a method of sensing electromagnetic signals associated with a sample in an electromagnetic resonator, the method comprising:
performing any method described or claimed herein to reduce the noise temperature of the electromagnetic resonator; and the method further comprising
performing the sensing of the electromagnetic signals using the second coupling.

### BRIEF DESCRIPTION OF DRAWINGS

Embodiments of the disclosure will now be described in detail, by way of example only, with reference to the accompanying drawings, in which:

FIG. 1 shows a first example of an apparatus comprising an electromagnetic resonator;

FIG. 2 shows a second example of an apparatus comprising an electromagnetic resonator;

FIG. 3 shows a third example of an apparatus comprising an electromagnetic resonator;

FIG. 4 shows an optional refinement of the apparatus illustrated in FIG. 1;

FIG. 5 shows an optional refinement of the apparatus illustrated in FIG. 2;

FIG. 6 is a flow chart illustrating a method of using apparatus such as that described with reference to FIG. 1 and FIG. 2 in an EPR system;

Other examples are contemplated and will be appreciated by the skilled addressee having read the present disclosure. In the drawings like reference numerals are used to indicate like elements.

### Specific Description

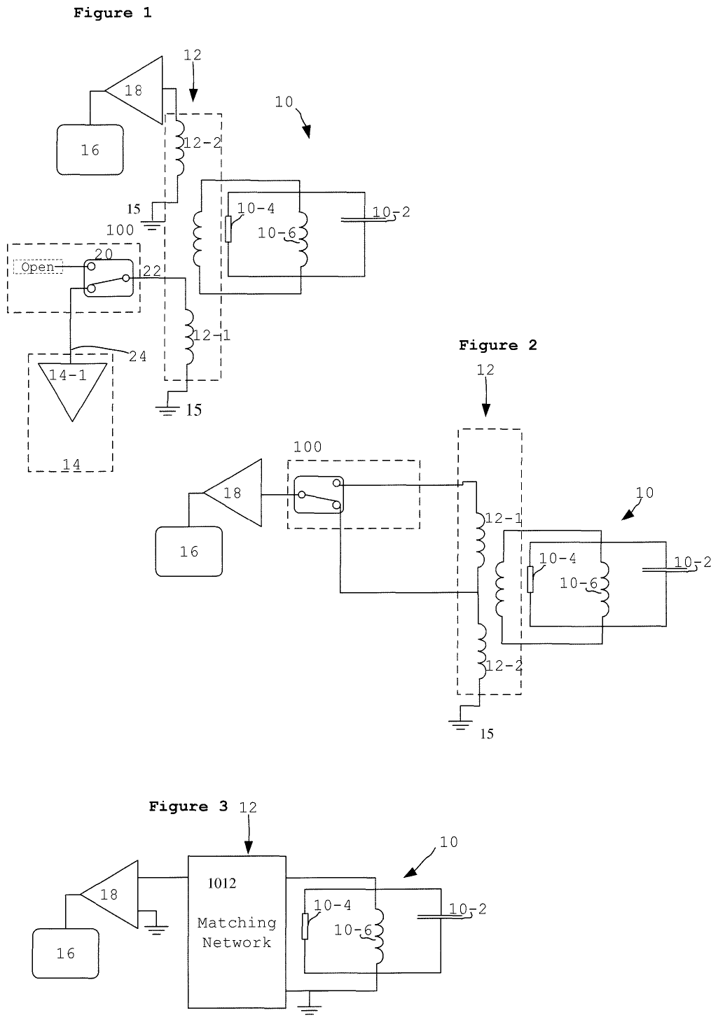

FIG. 1 shows an apparatus comprising an electromagnetic resonator 10, a coupler 12, and a cold load 14. Also shown is a receiver 16 and a low noise amplifier 18 connected between the coupler 12 and a receiver 16 (e.g. at the “front end” of the receiver 16).

The coupler 12 shown in FIG. 1 comprises a first coupling element 12-1 arranged for electromagnetic coupling (e.g., inductive and/or capacitive coupling) with the resonator 10. The first coupling element 12-1 is connected to the cold load 14 by a switching element 100. The coupler 12 also comprises a second coupling element 12-2, also arranged for electromagnetic coupling with the resonator 10 and connected to an input of the receiver 16 such as via the low noise amplifier 18.

The first coupling element 12-1 may thus provide an auxiliary coupler 12, in addition to the sensing coupler (second coupling element 12-2) which may typically be used for sensing electromagnetic fields associated with the sample in EPR, NMR, qubits, and like systems.

The cold load 14 in the embodiment of FIG. 1 is provided by an input of a low noise amplifier (LNA) 14-1.

The resonator 10 comprises some inductance and some capacitance and, optionally, some resistive impedance configured such that it can store energy capacitively (e.g., associated with electric field) and inductively (e.g. associated with magnetic field) and be driven to oscillate by the application of a time varying electromagnetic field. The resonator 10 typically exhibits resonance in one or more modes, each associated with a frequency, f₀, of the oscillator or one of its harmonics. Also illustrated is a mutual inductance, arising from inductive coupling between the resonator 10 and the coupler 12. It will be appreciated in the context of the present disclosure that such mutual inductance is not necessarily provided by any specific electrical component present in the resonator 10 but rather the arises from electromagnetic interaction between the resonator 10 and the coupler 12.

In operation, the switching element 100 is operated to connect the first coupling element 12-1 to the cold load 14. The resonator 10 may be at ambient temperature. The coupling between the resonator 10 and the first coupling element 12-1 causes the resonator 10 to move towards equilibrium with the cold load 14. This enables the noise temperature of the resonator 10 to be reduced, which may improve the signal to noise ratio of measurements.

The nature of this equilibrium may be determined by the relative degree of coupling between, on the one hand, the resonance modes of the resonator 10 and the first coupling element 12-1 and, on the other hand, the resonance modes of the resonator 10 and the electromagnetically lossy materials internal to the resonator out of which it is made, where the lossiness of these materials (e.g. the finite electrical surface conductivity of cavity walls) determines the resonator's intrinsic quality factor. In the case where the coupling between the first coupling element 12-1 and the resonance modes of the resonator 10 is greater, then the equilibrium noise temperature of the modes of the resonator 10 will be closer to the noise temperature of the cold load 14 than to that of the surroundings. If the coupling with the cold load 14 dominates then the equilibrium noise temperature of the modes will be dominated by the noise temperature of the cold load 14. Accordingly, the first coupling element 12-1 may be overcoupled with the resonator 10.

After the noise temperature of the resonator 10 has been allowed to approach thermal equilibrium with the cold load 14, the switching element 100 can be operated to disconnect the first coupling element 12-1 from the cold load 14. This may also disable the first coupling element 12-1, e.g. by providing an open circuit. The resonator 10 can then be excited by the application of electromagnetic energy, which may be applied using the second coupling element 12-2—(e.g., from a microwave source, not shown). This excites the sample held in the cavity to generate a time varying electromagnetic field, such as a free induction decay. This time varying electromagnetic field then couples with the second coupling element 12-2 to generate an electrical signal in the second coupling element 12-2, which is sensed by the receiver 16. This response of the sample to the stimulus may be measured while the noise temperature of the resonator 10 remains reduced, thereby improving the achievable signal to noise ratio.

The resonator 10 is represented in FIG. 1 as an equivalent circuit made of lumped components. It will be appreciated in the context of the present disclosure that this is merely schematic and such a resonator 10 may be implemented in any of a variety of ways. Examples of such resonator 10s include resonant circuits, such as RLC circuits having lumped and/or distributed impedances, and cavity resonators, such as EPR resonators. In terms of cavity resonators, microwave resonant cavities are of particular utility but any other type of cavity resonator may be used such as a cavity magnetron, a cavity loaded with a dielectric object such as a ring, Fabry-Perot cavities, or a resonator based on a tube waveguide such as a Klystron. In addition to cavity resonators, other examples of resonators include loop-gap resonators, split-ring resonators, dielectric resonators, transmission-line resonators, coplanar-waveguide resonators, and so forth.

The cold loads described and claimed herein may be provided by any appropriate electrical connection having a lower noise temperature than the noise temperature associated with ambient temperature, which may be around 20° C. The noise temperature in question may be the noise temperature at the resonant frequency of the resonator 10—e.g. at the frequency of the resonator's operational mode. The cold load 14 may be passive or active. For example, a passive cold load may be provided by physically cooling a passive termination, such as a resistor. This cooling may be provided cryogenically, e.g., through immersion into a bath of liquid nitrogen, or liquid helium, or by being thermally connected to the cold plate of a refrigerator such as a pulse-tube cooler or similar. An active cold load may be provided by a conduction channel of a high mobility transistor, such as may be found in the input of a low noise amplifier (LNA). Examples of commercially available active cold loads include the input (gate) of a Hewlett-Packard Microwave type HFET-1000 field-effect transistor (FET) or a Mitsubishi tyoe 1402 FET; or the input (base) or an Infineon SiGe type BFP640 heterojunction bipolar transistor (HBT); or the input of a Qorvo QPL9547EVB low noise amplifier (LNA) integrated circuit. The repurposing low-noise amplifiers for use as cold loads has a long history. The paper entitled “An Active “Cold” Noise Source”, by R. H Frater and D. W. William, page 344-347, IEEE TRANSACTIONS ON MICROWAVE THEORY AND TECHNIQUES, VOL. MTT-29, NO, 4, April 1981, provides a relatively early example of the art. A more recent example is: “PERFORMANCE ASSESSMENT OF AN LNA USED AS ACTIVE COLD LOAD” S.S. Søbjærg, J. E. Balling, and N. Skou, IEEE proceedings of IGARSS 2015. The characterization of the input noise of transistor-based amplifiers (using both discrete devices and ICs) is pedagogically covered in Chapter 8 (“Low noise techniques”) of THE ART OF ELECTRONICS, Third Edition, Paul Horowitz & Winfield Hill, Cambridge University Press.

FIG. 2 shows a further apparatus comprising an electromagnetic resonator 10 and a coupler 12 for coupling the resonator 10 to a receiver 16 via a low noise amplifier, LNA, 18. The electromagnetic resonator 10 in the apparatus illustrated in FIG. 2 is identical to that described above with reference to FIG. 1. However, unlike the apparatus shown in FIG. 1, the apparatus illustrated in FIG. 2 is arranged so that the input of the LNA 18 of the receiver 16 can be used to provide the cold load. To achieve this, a switching element 100 is provided which has:
a first terminal connected to the input of the LNA 18,
a second terminal connected by the first coupling element 12-1 in series with the second coupling element 12-2 to a reference voltage, such as ground or virtual ground,
a third terminal which is connected to the connection between the first coupling element 12-1 and the second coupling element 12-2, so that it is connected by the second coupling element 12-2 to the reference voltage 15.

It can this be seen that the switching element 100 is configured to selectively connect either (a) the series connection of both the first coupling element 12-1 and the second coupling element 12-2 to the input of the LNA, or (b) just the second coupling element 12-2 to the input of the LNA.

The switching element 100 may have a switching time, t_{switch}, which is small compared with a thermalisation time of the electromagnetic resonator 10, for example wherein

$${t}_{switch} ≪ \frac{{Q}_{0}}{2 π f}$$

### Where:

Q₀ is the Q-factor of the electromagnetic resonator 10 and
f is the resonant frequency of the electromagnetic resonator 10.

This can enable the sensing element to be connected for the reading out of signals before the resonator 10 has thermalized to ambient temperature.

In operation, the switching element 100 is first operated to connect the first terminal to the second terminal. This connects the series connection of both the first coupling element 12-1 and the second coupling element 12-2 to the input of the LNA. In this arrangement, the coupler 12 may be overcoupled with the resonator 10. The noise temperature of the resonator 10 can then be allowed to move toward, and perhaps to reach, the noise temperature of the input of the LNA.

After the noise temperature of the resonator 10 has been allowed to approach thermal equilibrium with the input of the LNA, the switching element 100 can be operated to connect the third terminal of the switching element 100 to the input of the LNA. This disables the first coupling element 12-1 and leaves just the second coupling element 12-2 able to provide coupling with the resonator 10. In this arrangement, the coupler 12 may be critically coupled with the resonator 10. The resonator 10 can then be excited by the application of electromagnetic energy, which may be applied using the second coupling element 12-2 so that the sample can be interrogated as described above with reference to FIG. 1.

It can therefore be seen that the apparatus may be arranged so that the cold load is provided by the input of a low noise amplifier, which may itself be the input of a receiver used to sense the electromagnetic field associated with the sample in the resonator 10 (e.g., the free induction decay).

FIG. 3 shows a further apparatus comprising an electromagnetic resonator 10. In this example the electromagnetic resonator 10 is electrically coupled by a coupler 12 which provides coupling via the electric field (as opposed to inductively e.g., via the magnetic field). This may be done by resistive electrical connections and/or by capacitive coupling. In the example illustrated in FIG. 3, the coupler 12 is provided by a controllable matching network 1012 and the electromagnetic resonator 10 comprises an LCR circuit.

In the arrangement shown in FIG. 3, the matching network 1012 is connected to the resonator 10 so that voltage across the resonator 10 is provided to an input of the matching network. An output of the matching network is connected to the input of an LNA 18 of the receiver 16. It will be appreciated in the context of the present disclosure that such an apparatus may be used in an NMR system, e.g., where the electromagnetic resonator 10 could be provided by the transmit/receive coil of the NMR system.

The matching network 1012 is controllable to provide two different modes of operation, and to switch between those two modes. In the first mode the matching network 1012 provides a first coupling between the electromagnetic resonator 10 and the input of the front-end LNA of a receiver. In the second mode the matching network provides a second coupling, different from the first coupling, between the electromagnetic resonator 10 and the input of an LNA of a receiver. The first coupling may provide a greater coupling than the second coupling. For example, the first coupling may be overcoupled and the second coupling may be critically coupled.

In operation, the matching network 1012 is first operated in the first mode, and it is kept in the first mode while the noise temperature of the resonator 10 approaches the noise temperature of the input of the LNA. Then, when the noise temperature of the resonator 10 has reached the desired level, the matching network is switched into the second mode to provide critical coupling between the input of the LNA and the resonator 10 so that signals generated in the resonator 10 can be sensed by the receiver.

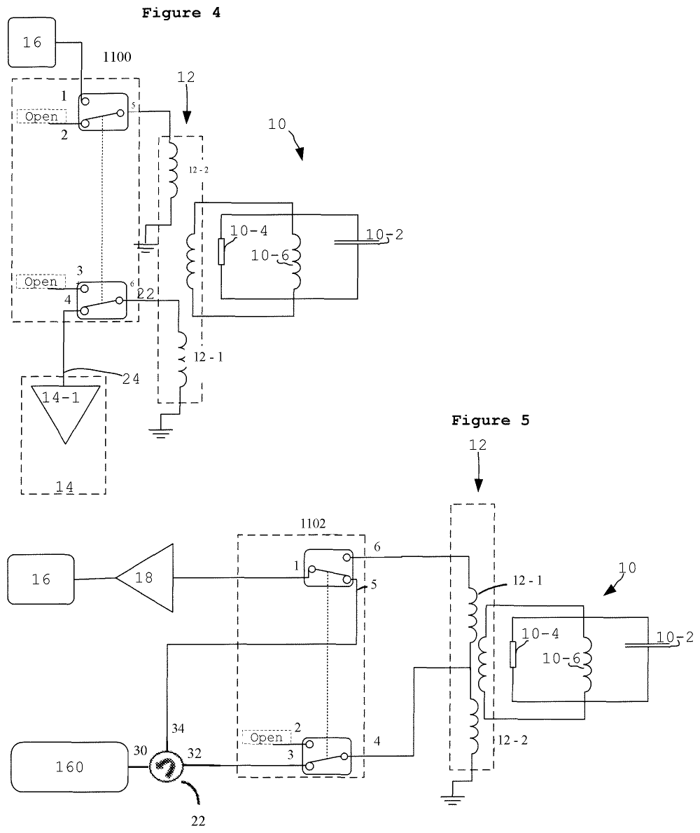

FIG. 4 illustrates a possible refinement of the apparatus illustrated in FIG. 1. In FIG. 4 the electromagnetic resonator 10 and the first coupling element 12-1 and the second coupling element 12-2 are identical to those elements described above with reference to FIG. 1. However, the switching element is different in that it is provided by a switching arrangement 1100 configured so that:
(a) when the first coupling element 12-1 is connected to the cold load the second coupling element 12-2 is disabled, and
(b) when the second coupling element 12-2 is connected to the receiver, the first coupling element 12-1 is disabled.

In particular, the switching arrangement shown in FIG. 4 has six terminals. A first terminal 1 is connected to a receiver 16 such an EPR or NMR bridge, and a second terminal 2 and a third terminal 3 are both disconnected—e.g., they each provide an open circuit termination. A fourth terminal 4 is connected to the cold load, a fifth terminal 5 is connected to the first coupling element 12-1 and the sixth terminal 6 is connected to the second coupling element 12-2.

In operation, the switching arrangement 1100 is first operated so that the fifth terminal 5 is connected to the second terminal 2 and the fourth terminal 4 is connected to the sixth terminal 6. In this state the first coupling element 12-1 is connected to the cold load 14, which may be provided by the input 24 of the LNA 14-1 and the second coupling element 12-2 is disconnected from the receiver and instead it is connected to open circuit termination and hence disabled. With the switching arrangement 1100 in this state, the coupling between the first coupling element 12-1 and the electromagnetic resonator 10 allows the noise temperature of the resonator 10 to approach that of the cold load 14. When the noise temperature of the resonator 10 has been reduced to a desired level, the switching arrangement 1100 is operated to connect the first terminal to the sixth terminal and to connect the third terminal to the fifth terminal. In this state the first coupling element 12-1 is disconnected from the cold load and connected to an open circuit termination and is hence disabled, whereas the second coupling element 12-2 is connected to the receiver 16. It can thus be seen that signals generated in the second coupling element 12-2 by electromagnetic fields from the resonator 10 can be provided to the receiver 16 while the cold load 14 is disconnected.

FIG. 5 shows a possible implementation of the apparatus shown in FIG. 2, and other implementations of the present disclosure in which the input of the LNA of the receiver is also used to provide the cold load. The coupler 12 and the resonator 10 of the apparatus shown in FIG. 5 is identical to that described above with reference to FIG. 2. It is different from that shown in FIG. 2 in that it also comprises a source of electromagnetic energy, such as an RF source for NMR interrogation or a microwave source for EPR interrogation and a circulator.

The circulator 22 has an input connection 30, an input/output connection 32, and an output connection 34. It is configured so that signals received at the input 30 are provided as output at the input/output connection 32. It is further configured so that signals received at the input/output 32 connection are provided as output at the output connection 34.

The input connection 30 of the circulator 22 is connected to the source of electromagnetic energy 160. The output connection 34 and the input/output connection 32 are switchably connected, by the switching arrangement 1102, to the coupler 12 and to the input of the LNA 18 of the receiver 16, as will be described below.

The switching arrangement has:
a first terminal 1 connected to the input of an LNA of the receiver 16,
a second terminal 2 connected to an open circuit termination,
a third terminal 3 connected to the input/output connection of the circulator,
a fourth terminal 4 connected to the connection between the first coupling element 12-1 and the second coupling element 12-2, so that it is connected to the reference voltage by the second coupling element 12-2;
a fifth terminal 5 connected to the output connection of the circulator; and
a sixth terminal 6 connected by the first coupling element 12-1 and the second coupling element 12-2 in series to the reference voltage. The switching arrangement 1102 is operable to switchably connect the first terminal 1 to either one or the other of the fourth and fifth terminals 4, 5. It is also operable to switchably connect the sixth terminal 6 to either one or the other of the second and third terminals 2, 3.

Accordingly, it is operable to switch between:
a first state in which the input of the LNA is connected by the first coupling element 12-1 in series with the second coupling element 12-2 to the reference voltage;
a second state in which the first coupling element 12-1 is connected to an open circuit termination to disable it while the output of the circulator is connected to the input of the LNA, and the input/output connection of the circulator is connected to the second coupling element 12-2;

In operation, the switching arrangement 1102 is first placed in the first state so that both the first coupling element 12-1 and the second coupling element 12-2 are connected in series to the input of the LNA. In this configuration, the resonator 10 may be overcoupled to the coupler 12. The switching arrangement is held in this state while noise temperature of the resonator 10 is reduced towards that of the input of the LNA. When the noise temperature of the resonator 10 has reached a desired level, the switching arrangement can be switched into the second state. In this configuration, the resonator 10 may be critically coupled to the coupler 12. Before the noise temperature of the resonator 10 has returned to the ambient level, the source of electromagnetic energy applies an excitation signal to the resonator 10 via the circulator and the second coupling element 12-2. This excites the resonator 10 and the electromagnetic fields provided from the resonator 10 in response to this excitation cause electrical signals in the second coupling element 12-2. These signals are then provided, via the circulator, to the input of the LNA and then to the receiver 16.

The circulator may comprise 4-terminal hybrid or a 3-terminal circulator but in terms of optimizing the signal-to-noise ratio of an EPR/NMR measurement, a circulator is the best option. With a hybrid, only half of the EPR signal from the resonator 10 gets routed to the receiving LNA; the other half gets wasted. There is not such waste with a circulator.

The cold load described herein may be an active cold load or a passive cold load. To provide an active cold load a commercial LNA may be used. An “Active Cold Load” may also be known as an “Active Cold Noise Source”.

The coupling elements described herein may be provided by any coupling able to link the electromagnetic field (mode) inside of the resonator 10 to the outside world (typically through a cable or waveguide). It could take the form of a loop or solenoid or wire (coupling to the mode's magnetic field), but it could also take the form of a stub of wire (coupling capacitively to the mode's electric field) or a “slit” or aperture at the end of a waveguide. These and other types of coupling can be used.

The switching elements between the coupled and the cold load should be
(a) Sufficiently fast (transition time <<warm up time of cavity) lest one runs out of time to do the EPR/NMR measurement before the thermal photons return.
(b) Sufficiently low loss: lest the switch itself injects thermal noise (=photons) into the ultra-quiet signal path.
(c) Sufficiently well-designed=“high isolation”: so as not to inject (generally via capacitive coupling inside transistors) glitches or interference (on the switches power supply and/or control lines) into the same ultra-quiet signal path.

One appropriate switch is a 5-6000 MHz Broadband SPDT Switch supplied by Qorvo (RTM) under part number RFSW1012, https://www.qorvo.com/products/p/RFSW1012.

It will be appreciated in the context of the present disclosure that the switching arrangements described with reference to FIG. 4 and FIG. 5 may be provided by two separate single pole double throw switches, which may be ganged together so they operate in unison, or it may be provided by a double pole double throw switch. Other types of switching arrangement may also be used. Such arrangements may employ a mechanical tie bar between the illustrated switches so as to toggle (exclusively) between two modes identified above—e.g. “resonator over coupled to cold load” and “resonator interrogated by EPR/NMR bridge” epochs. When toggling the switch, one connection is broken while the other connection is made. There could be two separate switches (made of semiconductors-PIN diodes, on an integrated circuit—a “chip”).

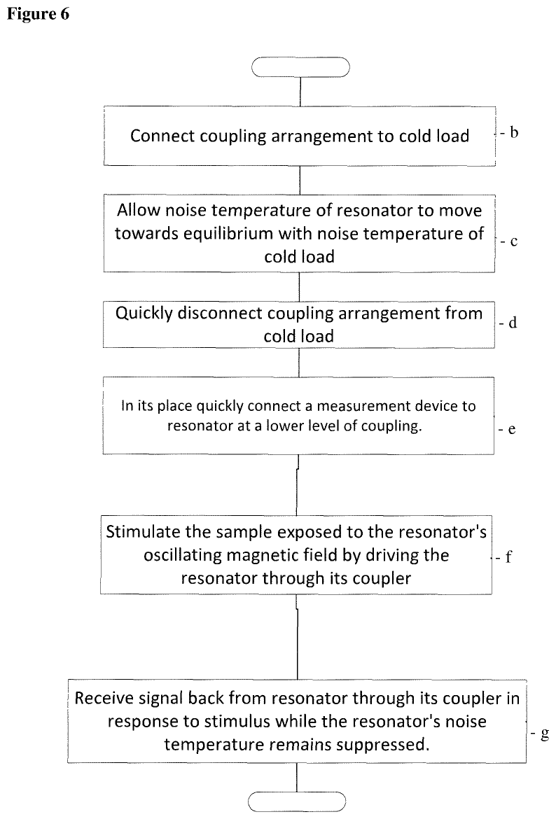

In the context of the above discussion it will be appreciated that the principles of the present disclosure may be applied to a wide variety of systems. In many of these embodiments, the method may follow the outline illustrated in FIG. 6, irrespective of the particular detail of the hardware used. The method may proceed as follows:
(a) Provide a sample in an electromagnetic resonator exposed to the electromagnetic fields of the resonator (e.g., its resonance modes)
(b) Connect the resonator to a cold load via a coupling arrangement, which is preferably overcoupled with the cold load.
(c) Allow the noise temperature of the resonator to move towards thermal equilibrium with the cold load (e.g. by exchange of energy via the coupling arrangement).
(d) Disconnect the coupling arrangement from the cold load.
(e) Quickly connect a measurement device to the resonator via the coupling arrangement.
(f) Stimulate the sample by driving the resonator through the coupling arrangement.
(g) Measure the response of the sample to the stimulus while the resonators noise temperature remains suppressed.

In one example of this method, it may be used in an EPR apparatus for performing an EPR measurement of a sample. In such a method the resonator would be provided by a microwave resonant cavity, positioned in a swept B₀ field. The coupling arrangement would be provided by:
an auxiliary coil, overcoupled with the cavity to provide the auxiliary coupling described herein, and
a standard EPR coil, critically coupled with the cavity and connected to the EPR bridge for sensing EPR signals of the sample in the cavity.

In another example of this method, it may be used in an NMR apparatus for performing an NMR measurement of a sample. In such a method the resonator would be provided by the transmit/receive coil of the NMR system. The coupling arrangement could be provided by a controllable matching network, such as that described with reference to FIG. 3.

In another example of this method, the sample may be provided by a spin in a qubit of a quantum computer and the resonator provided by a resonant length of co-planar waveguide.

Any feature of any one of the examples disclosed herein may be combined with any selected features of any of the other examples described herein. For example, features of methods may be implemented in configured suitably hardware, and the configuration of the specific hardware described herein may be employed in methods implemented using other hardware.

It will be appreciated from discussion above that the embodiments shown in the Figures are merely exemplary, and include features which may be generalised, removed or replaced as described herein and as set out in the claims. With reference to the drawings in general, it will be appreciated that schematic functional block diagrams are used to indicate functionality of systems and apparatus described herein. It will be appreciated however that the functionality need not be divided in this way, and should not be taken to imply any particular structure of hardware other than that described and claimed below. The function of one or more of the elements shown in the drawings may be further subdivided, and/or distributed throughout apparatus of the disclosure. In some embodiments the function of one or more elements shown in the drawings may be integrated into a single functional unit.

A general operational device, such as a controller or other appropriate collection of logic, may be provided to control the switching of the embodiments described and claimed herein. In some examples the functionality of the controller may be provided by a general purpose processor, which may be configured to perform a method according to any one of those described herein. In some examples the controller may comprise digital logic, such as field programmable gate arrays, FPGA, application specific integrated circuits, ASIC, a digital signal processor, DSP, or by any other appropriate hardware. In some examples, one or more memory elements can store data and/or program instructions used to implement the operations described herein. Embodiments of the disclosure provide tangible, non-transitory storage media comprising program instructions operable to program a processor to perform any one or more of the methods described and/or claimed herein and/or to provide data processing apparatus as described and/or claimed herein. The controller may comprise an analogue control circuit which provides at least a part of this control functionality. An embodiment provides an analogue control circuit configured to perform any one or more of the methods described herein.

The above embodiments are to be understood as illustrative examples. Further embodiments are envisaged. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

1. An apparatus comprising:
an electromagnetic resonator configured to support an oscillating electromagnetic field in a sample;
a cold load having a noise temperature lower than the noise temperature of the electromagnetic resonator;
a coupler controllable to provide:
a first coupling between the electromagnetic resonator and the cold load to reduce the noise temperature of the electromagnetic resonator;
a second coupling, different from the first coupling, to the electromagnetic resonator for sensing an electromagnetic field associated with the sample.

2. The apparatus of claim 1 wherein the coupler is configured to disable the first coupling prior to the sensing.

3. The apparatus of claim 1, or 2 wherein the coupler is arranged so that a coupling factor of the first coupling is greater than a coupling factor of the second coupling, for example wherein the first coupling is overcoupled.

4. The apparatus of any preceding claim wherein the cold load is provided by an input of a low noise amplifier.

5. The apparatus of any preceding claim comprising a switching element between the coupler and the cold load, the switching element being operable to disable the first coupling.

6. The apparatus of claim 5 wherein the switching element has a sufficiently low insertion loss that the noise temperature at its connection to the coupler is substantially equal to the noise temperature of the cold load.

7. The apparatus of claim 5 or 6 wherein the switching element comprises a switchable conduction channel and provides sufficiently high isolation of the switchable conduction channel that the noise temperature at its connection to the coupler element is substantially equal to the noise temperature of the cold load.

8. The apparatus of claim 5 wherein the coupler comprises:
an auxiliary coupler connectable to the cold load wherein the auxiliary coupler provides the first coupling,
a sensing coupler for connection to a receiver for performing the sensing, wherein the sensing coupler provides the second coupling; and
wherein the coupling factor of the auxiliary coupler to the electromagnetic resonator is greater than the coupling factor of the sensing coupler to the electromagnetic resonator.

9. The apparatus of claim 8 wherein the switching element switchably connects the cold load to the auxiliary coupler.

10. The apparatus of claim 8 or 9 wherein the cold load is provided by a low noise amplifier input of a receiver for performing the sensing.

11. The apparatus of claim 10 wherein the switching element is switchable from (a) a cooling mode in which it connects both the auxiliary coupler and sensing coupler to the low noise amplifier input of a receiver; to (b) a sensing mode in which it connects only the sensing coupler to a low noise amplifier input of the receiver.

12. The apparatus of any of claims 5 to 11 wherein the switching element is provided by a microwave switch.

13. The apparatus of any of claims 5 to 12 wherein the switching element has a switching time, t_{switch}, which is small compared with a thermalisation time of the electromagnetic resonator, for
$${t}_{switch} ≪ \frac{{Q}_{0}}{2 π f}$$
Where:
Q₀ is the Q-factor of the electromagnetic resonator and
f is the resonant frequency of the electromagnetic resonator.

14. The apparatus of claim 13 wherein the switching time is less than 20% of the thermalisation time, for example 10% or less.

15. The apparatus of any preceding claim wherein the second coupling is substantially critically coupled.

16. An electron paramagnetic resonance, EPR, system comprising the apparatus of any preceding claim, wherein the electromagnetic resonator is provided by a resonant cavity disposed in a magnetic field, B₀, the cavity configured so that the sample can be disposed in the cavity and the sensing comprises an EPR measurement of the sample.

17. A nuclear magnetic resonance, NMR, system comprising the apparatus of any preceding claim, wherein the electromagnetic resonator is provided by a transmit/receive coil of the NMR system disposed in a magnetic field, B₀, and the sensing comprises an NMR measurement of the sample.

18. The apparatus of any preceding claim wherein the cold load comprises at least one of: a cryogenic load, and an active cold noise source such as an input of a low noise termination or a low noise amplifier (LNA).

19. A method of reducing the noise temperature of an electromagnetic resonator configured to support an oscillating magnetic field in a sample, the method comprising:
providing a first coupling between the electromagnetic resonator and a cold load having a noise temperature lower than a noise temperature of the electromagnetic resonator; and,
when the noise temperature of the electromagnetic resonator has been reduced, providing a second coupling to the electromagnetic resonator for sensing an electromagnetic field associated with the sample, the first coupling being different from the second coupling.

20. The method of claim 19 comprising disabling the first coupling prior to performing the sensing.

21. The method of claim 20 wherein providing the second coupling comprises disconnecting the cold load from a coupler arranged for coupling with the electromagnetic fields associated with the sample, wherein the sensing is performed after the disconnecting.

22. The method of claim 21 wherein the disconnecting is performed in a switching time, t_{switch}, which is small compared with a thermalisation time of the electromagnetic resonator, for example wherein
$${t}_{switch} ≪ \frac{{Q}_{0}}{2 π f}$$
Where:
Q₀ is the Q-factor of the electromagnetic resonator and
f is the resonant frequency of the electromagnetic resonator.

23. The method of any of claims 19 to 22 wherein a coupling factor of the first coupling is greater than a coupling factor of the second coupling, for example wherein the first coupling is overcoupled.

24. The method of any of claims 19 to 23 wherein the cold load is provided by an input of a low noise amplifier.

25. A method of preparing an electron paramagnetic resonance, EPR, apparatus for performing an EPR measurement of a sample in a resonant cavity of the apparatus, the method comprising performing the method of any of claims 19 to 24 to reduce the noise temperature of the cavity.

26. A method of preparing a nuclear magnetic resonance, NMR, apparatus for performing an NMR measurement of a sample in a transmit/receive coil of the NMR system, the method comprising performing the method of any of claims 19 to 24 to reduce the noise temperature of the transmit/receive coil.

27. A method of sensing electromagnetic signals associated with a sample in an electromagnetic resonator, the method comprising:
performing the method of any of claims 19 to 24 to reduce the noise temperature of the electromagnetic resonator; and the method further comprising
performing the sensing of the electromagnetic signals using the second coupling.
